(19) United States
(12) Patent Application Publication
(10) Pub. No.: US 2020/0166408 A1
(43) Pub. Date: May 28, 2020

(54) SUSPENDED-MEMBRANE THERMAL DETECTOR COMPRISING A DEFORMABLE ABSORBER

(71) Applicant: Commissariat A L'Energie Atomique et aux Energies Alternatives, Paris (FR)

(72) Inventors: Abdelkader ALIANE, Grenoble Cedex 9 (FR); Jean-Louis OUVRIER-BUFFET, Grenoble Cedex 9 (FR)

(73) Assignee: Commissariat A L'Energie Atomique et aux Energies Alternatives, Paris (FR)

(21) Appl. No.: 16/687,794

(22) Filed: Nov. 19, 2019

(30) Foreign Application Priority Data
Nov. 23, 2018 (FR) 18 71743

(51) Int. Cl. G01J 5/04; G01J 5/06; H01L 37/00

(52) U.S. Cl. CPC G01J 5/046; H01L 37/00; G01J 5/061

(57) ABSTRACT

A thermal detector including a three-dimensional structure adapted for detecting electromagnetic radiation, suspended above and thermally insulated from a substrate, including a membrane and an absorber, the latter being formed on the basis of a shape-memory alloy and being adapted to have a flat detection configuration when its temperature is less than or equal to T₁ and a cooling curve configuration when its temperature is above an austenite start temperature Aₛ.

### TECHNICAL FIELD

The field of the invention is that of thermal detectors of electromagnetic radiation, for example infrared or terahertz, comprising a suspended membrane that is thermally insulated with respect to a substrate. The invention applies notably to the field of infrared or terahertz imaging, thermography, or detection of persons or of movement.

### PRIOR ART

Devices for detecting electromagnetic radiation may comprise a matrix of sensitive pixels each containing a thermal detector comprising an absorbent membrane suspended above a substrate that may contain a reading circuit. The absorbent membrane comprises an absorber of the electromagnetic radiation to be detected associated with a thermometric transducer, an electrical property of which varies in intensity as a function of heating of the transducer. The thermometric transducer may be a thermistor material such as a vanadium oxide or amorphous silicon, among others. The absorber is spaced from a reflector arranged at the level of the substrate so that together they form a quarter-wave interference cavity, improving the absorption of the electromagnetic radiation of interest.

However, as the temperature of the thermometric transducer largely depends on its environment, the absorbent membrane is insulated thermally from the substrate and from the reading circuit. Thus, the absorbent membrane may be suspended above the substrate by anchoring pillars, and is insulated thermally from the substrate by heat-insulating arms. These anchoring pillars and heat-insulating arms also have an electrical function, providing electrical connection of the absorbent membrane to the reading circuit.

FIG. 1A is a schematic sectional view of a thermal detector 1 similar to that described in the article by Li et al. titled Recent Development of Ultra Small Pixel Uncooled Focal Plane Arrays at DRS, Infrared Technology and Applications XXXIII, Proc. of SPIE, Vol. 6542, 65421Y, 2007. The thermal detector 1 comprises a three-dimensional structure 2 suspended above the substrate 10 by anchoring pillars 4 and thermally insulated from the latter by heat-insulating arms 5. The three-dimensional structure 2 comprises a lower stage formed by a membrane 9 containing a thermistor material 6, here a vanadium oxide, and comprises an upper stage formed by an absorber 7 of the incident infrared radiation. The absorber 7 extends in a flat manner above the membrane 9, while being connected thermally to the thermistor material 6. More precisely, the absorber 7 seems be formed from two parts 7.1, 7.2 made in one piece and from one and the same material: an upper peripheral part 70.1 that extends in a flat manner above the membrane 9, and a hollow vertical central part 70.2, which will rest on the membrane 9. However, the presence of the vertical central part 70.2 is liable to degrade the properties of the quarter-wave interference cavity and therefore decrease the absorption of the incident infrared radiation by the absorber 7.

Moreover, the thermal detector is likely to be subjected to high-power electromagnetic radiation, such as solar radiation or laser radiation. As the absorbent membrane is insulated thermally from the substrate, it may undergo strong heating that is likely to cause degradation of the properties of the thermometric transducer.

In this connection, FIG. 1B is a schematic sectional view of a thermal detector 1 described in the application KR101181248. The absorbent membrane 9 is suspended above the substrate 10 by anchoring and heat-insulating arms 8. It is adapted to deform locally under the effect of heating until it comes into contact with the substrate 10. This mechanical and therefore thermal contact causes cooling of the absorbent membrane 9, so that the temperature of the latter does not reach or does not exceed a threshold temperature Tₜₕ beyond which degradation of the properties of the thermistor material may occur. For this purpose, the absorbent membrane 9 comprises a fixed detecting part 90.1 at the level of which the thermistor material is arranged, and a deformable part 90.2 of the bimetal type adapted for making a thermal short-circuit between the absorbent membrane 9 and the substrate 10.

Thus, during excessive heating of the absorbent membrane 9, the deformable part 9.2 deforms by the bimetal effect until it comes into contact with the substrate 10, which causes cooling of the absorbent membrane 9. This cooling then causes the deformable part 9.2 to move away from the substrate 10. However, it appears that a continuous movement of vertical oscillation may develop owing to alternation of the phases of cooling on coming into contact with the substrate and of heating after loss of contact, which impairs the quality of thermal contact between the deformable part 90.2 and the substrate 10, and therefore impairs the cooling of the absorbent membrane 9.

### Presentation of the Invention

The invention aims at least partly to overcome the drawbacks of the prior art, and more particularly to propose a thermal detector having improved absorption of the electromagnetic radiation of interest, while ensuring good protection against high-power electromagnetic radiation.

For this purpose, the invention relates to a thermal detector adapted for detecting electromagnetic radiation, comprising:
a substrate;
a reflector of said electromagnetic radiation;
a three-dimensional structure adapted for detecting said electromagnetic radiation, suspended above the substrate and thermally insulated from the substrate, comprising:
   a membrane comprising a thermometric transducer,
   an absorber of said electromagnetic radiation,
      resting on the membrane and partly spaced from the latter, and connected thermally to the thermometric transducer,
      spaced with respect to the reflector so as to form a quarter-wave interference cavity for the electromagnetic radiation.

According to the invention, the absorber is:
formed on the basis of a shape-memory alloy having a so-called inverse martensitic transformation of a martensitic phase into an austenitic phase of said alloy starting from a so-called austenite start temperature Aₛ, and
adapted to have:
   a so-called detection configuration when its temperature is less than or equal to a first threshold temperature T₁, in which it extends in a flat manner in a plane parallel to the reflector, and
   a so-called cooling configuration when its temperature is above a predetermined second threshold temperature T₂ equal to the austenite start temperature Aₛ, in which it extends at least partly in a curved manner with respect to a plane parallel to the reflector.

Certain preferred but non-limiting aspects of this thermal detector are as follows.

The shape-memory alloy has a volume fraction χₘ of the martensitic phase. It may have the flat detection configuration when the volume fraction χₘ is greater than or equal to 0.95, and may have the cooling curve configuration when the volume fraction χₘ is less than 0.95.

The shape-memory alloy may have a volume fraction χₘ less than or equal to 0.05 when its temperature is greater than or equal to a so-called austenite finish temperature A_{f}, said austenite finish temperature A_{f} being below a predetermined threshold temperature Tₜₕ for protection of the thermometric transducer.

The deformable absorber may comprise a fixed part resting in contact with the membrane, and a free part adapted to deform as a function of the temperature of the deformable absorber and extending from the fixed part and spaced from the membrane.

The shape-memory alloy may be a metal alloy based on NiTi. The shape-memory alloy may be a metal alloy selected from Ti_{85.3-x}NiₓHf_{14.7} with x>50 at %, Ti₈₂₋ₓNiₓZr₁₈ with x>49 at %, Ti₇Ni₁₁Zr₄₃Cu₃₉₋ₓCoₓ with x>10 at %, Ti₅₀Ni₅₀₋ₓPtₓ with x<25 at %, Ti_{50.5}Ni_{24.5}Pd₂₅, Ti₅₁Ni₃₈Cu₁₁, Ti₅₀₋ₓNi₅₀Cuₓ with x>7.5 at %, or an alloy based on TiNiCuAlMn.

The deformable absorber may comprise an absorbent layer of shape-memory alloy having protuberances arranged on a face of the absorbent layer opposite the substrate.

The deformable absorber may comprise an absorbent layer of shape-memory alloy having at least one cut-out formed starting from a face of the absorbent layer opposite the substrate.

The substrate may have a flat upper face, in which the three-dimensional structure is held above the upper face of the substrate by heat-insulating arms, and by anchoring pillars that extend approximately orthogonally to the plane of the upper face of the substrate.

The substrate may comprise a reading circuit, the three-dimensional structure being connected electrically to the reading circuit by the anchoring pillars and by the heat-insulating arms.

The invention also relates to a method for fabricating the thermal detector according to any one of the preceding features, comprising the following steps:
supplying a substrate;
depositing at least one first sacrificial layer on the substrate;
making anchoring pillars through the first sacrificial layer;
making heat-insulating arms and a membrane containing a thermometric transducer on the first sacrificial layer;
depositing at least one second sacrificial layer so as to cover the heat-insulating arms and the membrane;
making the absorber on the second sacrificial layer, so that it rests at least partly on the membrane;
removing the first and second sacrificial layers.

### BRIEF DESCRIPTION OF THE DRAWINGS

Other aspects, aims, advantages and features of the invention will become clearer on reading the following detailed description of preferred embodiments of the invention, given as non-limiting examples, and made with reference to the appended drawings, in which:

FIGS. 1A and 1B, already described, are schematic views, in section (FIG. 1A) and in perspective (FIG. 1B), of a thermal detector according to two examples from the prior art;

FIGS. 2A and 2B are schematic sectional views of a detecting device according to one embodiment, and FIG. 2C is a graph that illustrates the temperature-dependent variation of the volume fraction of the martensitic phase in a shape-memory alloy;

FIGS. 3A to 3H illustrate different steps of a method for fabricating the detecting device according to a variant of the embodiment illustrated in FIGS. 2A and 2B;

FIGS. 4A and 4B are schematic sectional views of different thermal detectors according to embodiment variants.

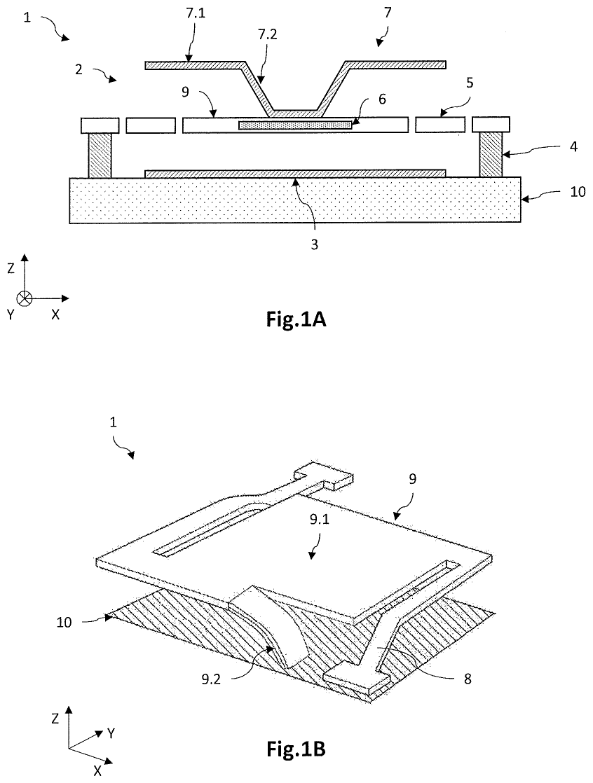

### DETAILED DISCLOSURE OF PARTICULAR EMBODIMENTS

In the figures and in the rest of the description, the same references represent elements that are identical or similar. Moreover, the various elements are not shown to scale, for the sake of clarity of the figures. Moreover, the various embodiments and variants are not exclusive of one another and may be combined with one another. Unless stated otherwise, the terms “approximately”, “about”, “of the order of” signify to within 10%, and preferably to within 5%. Moreover, the expression “comprising a” must be understood, unless stated otherwise, as “comprising at least one” and not as “comprising a single”.

The invention relates to a device for detecting electromagnetic radiation, for example infrared or terahertz radiation. The detecting device comprises one or more thermal detectors preferably particularly adapted for detecting infrared radiation of the LWIR (Long Wavelength Infrared) range, whose wavelength is between about 8 μm and 14 μm.

Each thermal detector comprises a three-dimensional structure, suspended above the substrate, and thermally insulated from the latter. The three-dimensional structure comprises several distinct functional stages superposed on one another, i.e. arranged opposite and parallel to one another. It thus comprises a membrane located in a lower stage and containing a thermometric transducer, and an absorber located in an upper stage. The absorber is adapted to absorb the electromagnetic radiation to be detected, and rests on the membrane while being partly spaced from the latter, and is connected thermally to the thermometric transducer.

Each thermal detector also comprises a reflector of the electromagnetic radiation to be detected, preferably located on the substrate. The absorber is spaced with respect to the reflector so as to form a quarter-wave interference cavity, thus making it possible to optimize the absorption of the infrared radiation to be detected by the absorber.

As described in detail hereunder, the absorber is said to be deformable and is adapted to deform as a function of its temperature, so as to pass from a first so-called detection configuration when its temperature is less than or equal to a predetermined first threshold temperature T₁, to a second so-called cooling configuration when its temperature is above a predetermined second threshold temperature T₂, and vice versa. In the detection configuration, the absorber extends in a flat manner in a plane parallel to the plane of the reflector, thus making it possible to maximize the absorption of the electromagnetic radiation to be detected. In the cooling configuration, the absorber extends in a curved manner with respect to a plane parallel to the plane of the reflector, thus minimizing the absorption of the electromagnetic radiation to be detected. In the rest of the description, the temperature T of the deformable absorber is approximately equal to the temperature of the membrane, owing to the thermal connection between these two elements. Thus, the temperature is assumed to be uniform, to a first approximation, within the three-dimensional structure, i.e. both in the deformable absorber and in the thermometric transducer membrane.

For this, the deformable absorber is made on the basis of at least one shape-memory alloy (SMA), i.e. from an alloy having a martensitic transformation. “On the basis of” means that the deformable absorber predominantly comprises said shape-memory alloy. In a known manner, and as described notably in the article by Choudhary and Kaur titled Shape memory alloy thin films and heterostructures for MEMS applications: A review, Sensors and Actuators A 242 (2016) 162-181, a martensitic transformation is a structural transition of the alloy, reversible and of the displacive type, as a function of temperature, between a martensitic phase (low-temperature crystallographic phase) and an austenitic phase (high-temperature crystallographic phase). The martensitic transformation has characteristic temperatures (at zero stress) that depend on the direction of the transformation. Thus, for the direct transformation (austenite to martensite), the temperatures of the start and end of transformation are conventionally designated Mₛ (for Martensite start temperature) and M_{f} (for Martensite finish temperature). For the inverse transformation (from martensite to austenite), the temperatures of the start and end of transformation are conventionally designated Aₛ (for Austenite start temperature) and A_{f} (for Austenite finish temperature). Also in a known manner, the martensitic transformation has a temperature hysteresis between cooling and heating of the alloy, so that the temperatures Mₛ and A_{f} are different from one another, just like the temperatures M_{f} and Aₛ.

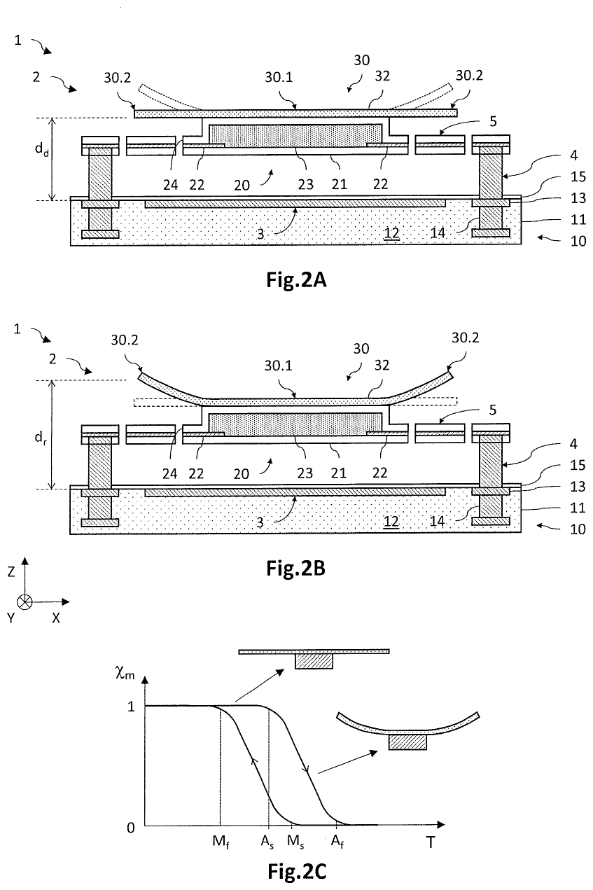

Referring to FIG. 2C, during the inverse martensitic transformation (from martensite to austenite), the volume fraction χₘ of the martensitic phase is greater than or equal to 0.95, or even equal to 1.0, when the temperature T of the shape-memory alloy is less than or equal to the temperature Aₛ. It then decreases as the temperature T increases and is less than or equal to 0.05, or even equal to 0, when the temperature T is greater than or equal to the temperature A_{f}. Moreover, during the direct martensitic transformation (from austenite to martensite), the volume fraction χₘ of the martensitic phase is less than or equal to 0.05, or even equal to 0, when the temperature T of the shape-memory alloy is greater than or equal to the temperature Mₛ. It then increases as the temperature T decreases and is greater than or equal to 0.95, or even equal to 1.0, when the temperature T is less than or equal to the temperature M_{f}.

In the context of the invention, the deformable absorber based on a shape-memory alloy has an austenite start temperature A equal to the second threshold temperature T₂ (starting from which the absorber curves). Thus, it deforms as a function of its temperature and may thus have:
a flat form (detection configuration) when its temperature T is less than or equal to the first threshold temperature T₁, which is equal to the martensite finish temperature M_{f} or to the austenite start temperature Aₛ, as a function of the direction, direct or inverse, of the martensitic transformation, and
a curved form (cooling configuration) when its temperature T is above the austenite start temperature Aₛ.

Thus, as presented in detail hereunder, the threshold effect associated with deformation of the shape-memory alloy is utilized to minimize the risks of degradation of the thermometric transducer connected with excessive heating, while optimizing the absorption of the electromagnetic radiation of interest in the absence of said excessive heating.

FIGS. 2A and 2B are schematic sectional views of a thermal detector 1 according to one embodiment, comprising a deformable absorber 30 in flat detection configuration (FIG. 2A) and in cooling curve configuration (FIG. 2B). A single thermal detector 1 is shown here, but the detecting device advantageously comprises a matrix of identical thermal detectors (sensitive pixels). The thermal detector 1 may have lateral dimensions in the XY plane (called pixel pitch) of the order of one to some tens of microns, for example equal to about 10 μm or even less.

Here, and for the rest of the description, a direct three-dimensional orthogonal coordinate system (X,Y,Z) is defined, where the (X,Y) plane is approximately parallel to the principal plane of the reading substrate 10 of the thermal detector 1, and where the Z axis is oriented in a direction approximately orthogonal to the principal plane of the reading substrate 10 and oriented towards the three-dimensional structure 2. In the rest of the description, the terms “lower” and “upper” are to be understood as relative to an increasing positioning on moving away from the reading substrate m in the +Z direction.

The thermal detector 1 comprises a substrate, advantageously functionalized, the so-called reading substrate 10, made in this example on the basis of silicon, comprising a reading circuit for controlling and reading the thermal detectors. Here, the reading circuit is in the form of a CMOS integrated circuit located in a supporting substrate 11. It comprises portions 13 of conductors, for example metallic, separated from one another by a dielectric material 12, for example a silicon-based mineral material such as a silicon oxide SiOₓ, a silicon nitride SiNₓ, or alloys thereof. It may also comprise active electronic elements (not shown), for example diodes, transistors, or passive electronic elements, for example capacitors, resistances, etc., connected by electric interconnections to the thermal detector 1 on the one hand, and to a connection stud (not shown) on the other hand, the latter being intended to connect the detecting device to an external electronic device. As an illustration, the conducting portions 13 and the conducting vias 14 may be made, for example, of copper, aluminium or tungsten. The copper or the tungsten may optionally be located between sublayers of titanium nitride, tantalum nitride or others. Here, the reading substrate 10 has an upper face boa formed notably by a surface of an inter-metal insulating layer 12 and a surface of conducting portions 13 of the last level of electrical interconnection.

The thermal detector 1 comprises a reflector 3, made of at least one material that is reflective with respect to the electromagnetic radiation to be detected. Advantageously, it is formed here from a portion of the conductor of the last level of electrical interconnection of the CMOS integrated circuit. Here, it is located in the substrate 10 and participates in defining the upper face boa of the substrate. As a variant, it may rest on the upper face boa of the substrate, or be spaced from the latter by a non-zero distance.

The upper face boa is advantageously covered with a protective layer 15, notably when the thermal detector 1 is produced using mineral sacrificial layers, which are then removed by chemical etching in HF (hydrofluoric acid) acid medium. The protective layer 15 then has a function of stopping etching, and is therefore adapted for providing protection of the supporting substrate 1b and of the inter-metal dielectric layers 12, when they are made of a mineral material, against HF chemical attack. This protective layer 15 thus forms a hermetic, chemically inert layer. It is electrically insulating to prevent any short-circuiting between the portions 13 of metal conductor. It may thus be made of alumina Al₂O₃, or of aluminium nitride or fluoride, or of intrinsic amorphous silicon. It may have a thickness between some tens and some hundreds of nanometres, for example between 10 nm and 500 nm, preferably between 20 nm and 100 nm.

The thermal detector 1 comprises a three-dimensional structure 2 adapted for detecting the electromagnetic radiation of interest, suspended above the substrate 10 by the anchoring pillars 4 and insulated thermally from the latter by heat-insulating arms 5. Moreover, the three-dimensional structure 2 is connected electrically to the reading circuit by the anchoring pillars 4 and the heat-insulating arms 5.

The anchoring pillars 4 are conducting studs made of at least one electrically conducting material, which extend along the Z axis from the reading substrate 10 to the three-dimensional structure 2. They are in contact with the portions 13 of conductors, and thus provide electrical connection of the three-dimensional structure 2 to the reading circuit. The anchoring pillars 4 may be made, for example, of copper, aluminium or tungsten, optionally encapsulated in at least one protective sublayer of titanium nitride, or other. Here, the heat-insulating arms 5 extend in a manner approximately coplanar with the membrane 20, and are formed here from an electrically conducting layer allowing electrical connection of the membrane 20 to the reading circuit, advantageously encapsulated in two dielectric layers, lower and upper, which contribute to stiffening of the heat-insulating arms 5.

The three-dimensional structure 2 comprises two separate functional stages superposed on one another. The functional stages are thus arranged in separate planes that are parallel to one another, and are opposite one another.

The first functional stage is a lower stage having a function of detecting the electromagnetic radiation. For this, it comprises the membrane 20 containing a thermometric transducer 23, i.e. an element having an electrical property that varies as it is heated. The membrane 20 extends in a flat manner parallel to the XY plane of the substrate 10. It is said to be fixed, as it is located at an approximately constant distance with respect to the substrate 10. Here, the thermometric transducer 23 is a thermistor material, for example such as a vanadium or titanium oxide, or amorphous silicon, but may as a variant be a capacitor formed by a pyroelectric or ferroelectric material, a diode (p-n or PIN junction), or a field-effect transistor with a metal/oxide/semiconductor structure (MOSFET).

Here, the membrane 20 is formed conventionally from a stack of a lower dielectric layer 21 made of a dielectric material, two electrodes 22 electrically insulated from one another by a lateral gap, a thermistor material 23 extending in contact with the polarization electrodes 22 and the lower dielectric layer 21, and an upper dielectric layer 24 covering the polarization electrodes 22 and the thermistor material 23, notably for protecting the thermistor material 23 during the chemical etching with hydrofluoric acid carried out subsequently.

The second functional stage is an upper stage having a function of absorbing the electromagnetic radiation to be detected. It thus comprises the deformable absorber 30, made on the basis of a shape-memory alloy advantageously adapted for absorbing the electromagnetic radiation. It rests on the membrane 20 and is connected thermally to the thermistor material 23, while being partly spaced from the latter. The deformable absorber 30 is thus adapted to deform as a function of its temperature and thus pass from a flat detection configuration to a cooling curve configuration, and vice versa.

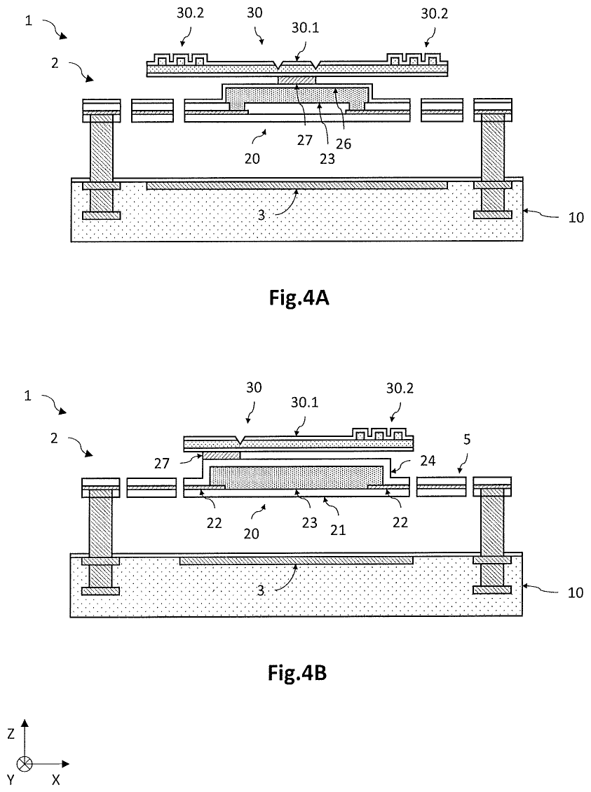

The deformable absorber 30 is formed from a fixed part 30.1, resting in contact with the membrane 20, here with the upper protective layer, and a so-called free part 30.2, i.e. able to deform, and spaced from the membrane 20 by a non-zero distance. In this example, the fixed part 30.1 is located at the centre of the deformable absorber 30, and the free part 30.2 extends peripherally around the fixed part 30.1. As a variant (cf. FIG. 4B), the fixed part 30.1 may be located at the edge of the deformable absorber 30, and the free part 30.2 may then extend from the fixed part 30.1 in one or two preferred directions.

Referring to FIG. 2A, the deformable absorber 30 is adapted to occupy a detection configuration in which it extends in a flat manner parallel to the XY plane of the substrate. The deformable absorber 30 may occupy the flat detection configuration when the shape-memory alloy has a volume fraction χₘ of the martensitic phase greater than or equal to 0.95, for example equal to 1.0, i.e. when its temperature is less than or equal to a first threshold temperature T₁, namely the martensite finish temperature M_{f} or the austenite start temperature Aₛ depending on the direct or inverse direction of the martensitic transformation.

In the flat detection configuration, the deformable absorber 30 is planar, so that its fixed part 30.1 and its free part 30.2 are spaced from the reflector 3 by a non-zero distance d_{d} approximately constant and uniform in the XY plane. The distance d_{d} is therefore temperature-constant while T is less than or equal to T₁. This distance is adjusted so as to form a quarter-wave interference cavity that is not perturbed, maximizing the absorption of the electromagnetic radiation to be detected by the deformable absorber 30. The deformable absorber 30 is spaced from the reflector 3 by a distance typically between 1 μm and 5 μm, preferably 2 μm, when the thermal detector 1 is designed for detecting infrared radiation comprised in the LWIR. Thus, the deformable absorber 30, in the flat detection configuration, makes it possible to maximize the absorption of the electromagnetic radiation of interest.

Referring to FIG. 2B, the deformable absorber 30 is adapted to occupy a cooling configuration for which the absorber extends in a curved manner with respect to a plane parallel to the XY plane of the substrate. It may occupy the cooling curve configuration when the shape-memory alloy has a volume fraction χₘ of the martensitic phase less than 0.95, for example equal to 0.5 or less, i.e. when its temperature is above a predetermined second threshold temperature T₂, namely here the austenite start temperature Aₛ.

In the cooling curve configuration, the deformable absorber 30 is curved, so that its fixed part 30.1 is spaced from the reflector 3 by the distance d_{d} but the deformed free part 30.2 is spaced from the reflector 3 by a variable non-zero distance dᵣ in the XY plane, the value of which depends on the temperature T. This distance dr then no longer corresponds to the distance d_{d}, so that the quarter-wave interference cavity is degraded. The absorption of the electromagnetic radiation by the deformable absorber 30, in the cooling curve configuration, is then decreased, which makes it possible to reduce the heating of the deformable absorber 30 and therefore lower its temperature as well as that of the thermistor material 23.

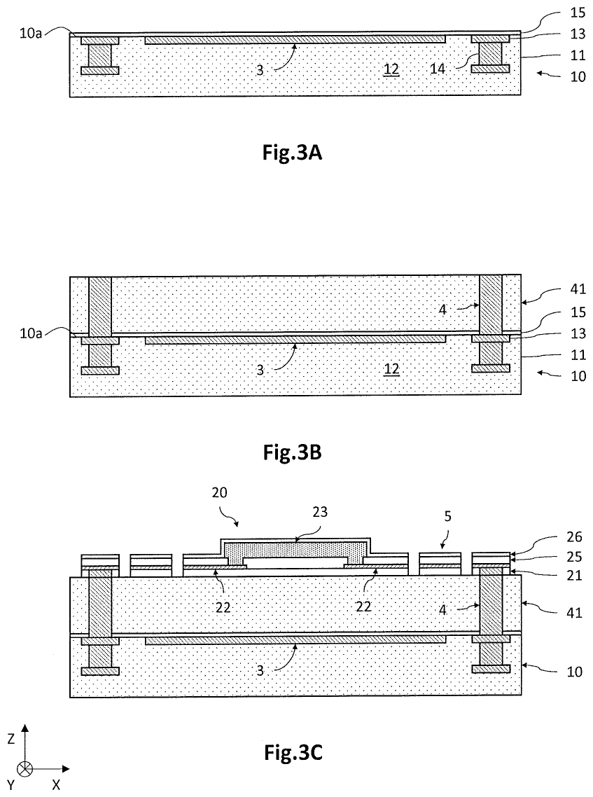

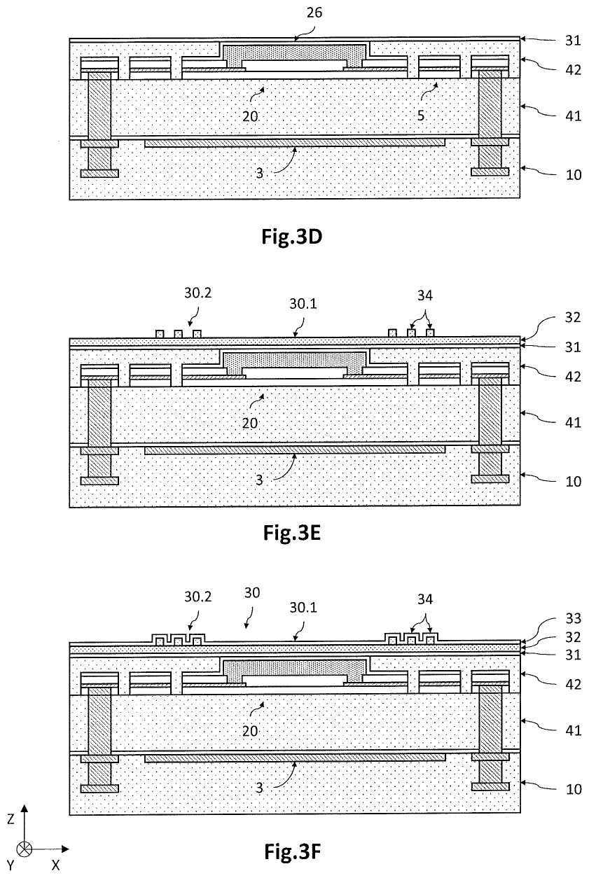

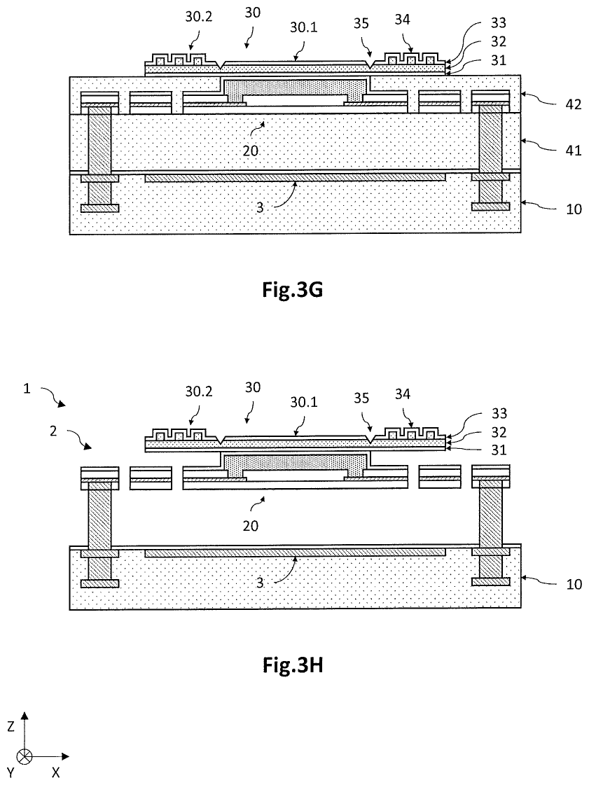

The deformable absorber 30 is made on the basis of a shape-memory alloy. It is formed from an absorbent layer 32 of shape-memory alloy, here advantageously encapsulated between two, lower and upper, protective layers (cf. FIG. 3A-3H). The protective layers are intended notably to protect the shape-memory alloy during a step of removing the sacrificial layers employed during fabrication of the thermal detector 1. They may be made for example of a silicon nitride SiN or a silicon oxide SiO, for example with a thickness of 10 nm.

In general, the shape-memory alloy is a metal alloy selected from the alloys based on NiTi, based on copper Cu, or based on iron Fe. The metal alloy is selected in such a way that the austenite start temperature Aₛ is equal to the temperature T₂, which is less than or equal to a predetermined temperature Tₜₕ for protection of the thermometric transducer. This protection temperature depends on the type of thermometric transducer, and may be of the order of 100° C. to 350° C., for example 200° C. Thus, the metal alloy may be made of a binary compound NiTi with an atomic proportion of nickel and of titanium that may or may not be equal, or of a ternary compound NiTiA where the additional chemical element A may be iron Fe, copper Cu, zirconium Zr, hafnium Hf, platinum Pt, palladium Pd, tungsten W, gold Au, or some other. It may thus be Ti₅₁Ni₃₈Cu₁₁, where the subscripts represent the atomic proportion of each chemical element in the alloy. We may mention for example: Ti_{85.3-x}NiₓHf_{14.7} with x>50% in at %, Ti₈₂₋ₓNiₓZr₁₈ with x>49% in at %, Ti₇Ni₁₁Zr₄₃Cu₃₉₋ₓCoₓ with x>10% in at %, Ti₅₀Ni₅₀₋ₓPtₓ with x<25% in at %, Ti_{50.5}Ni_{24.5}Pd₂₅, Ti₅₁Ni₃₈Cu₁₁, Ti₅₀₋ₓNi₅₀Cuₓ with x>7.5% in at %. It may also be an alloy based on TiNiCuAlMn whose austenite start temperature is less than or equal to 200° C. These alloys have a resistivity between 10⁻⁶ Ω·m and 4·10⁻⁵ Ω·m. The thickness of the absorbent layer 32 of shape-memory alloy is such that its impedance is approximately equal to that of a vacuum (resistance of the absorbent layer close to 377 Ω/sq) and may be between some nanometres and some tens of nanometres, for example between 5 nm and 25 nm. Preferably, the metal alloy is Ti₅₀₋ₓNi₅₀Cuₓ (resistivity 1.5×10⁻⁶ Ω·m) with thickness between 4 nm and 6 nm, and Ti_{85.3-x}NiₓHf_{14.7} (resistivity 2×10⁻⁶ Ω·m) with thickness between 5 nm and 10 nm. More precisely, as mentioned below, the absorbent layer 32 of shape-memory alloy advantageously has a constant thickness in the fixed part 30.1 and the free part 30.2. It may, however, comprise protuberances 34 (cf. FIG. 3H) located at the level of the free part 30.2, and/or at least one cut-out 35 (cf. FIG. 3H) located at the juncture between the fixed part 30.1 and the free part 30.2.

The absorbent layer 32 of shape-memory alloy of the deformable absorber 30 advantageously comprises a local variation of thickness, so as to provide more effective control of the direction of the deformation between the flat and curved configurations. In other words, to obtain deformation of the deformable absorber 30 such that the distance dr in cooling curve configuration is greater than the distance d_{d} in flat detection configuration, the absorbent layer 32 of shape-memory alloy comprises at least one projecting feature 34 (cf. FIG. 3H), i.e. at least one protuberance, located on a face of the deformable absorber 30 opposite the substrate to. These protuberances 34 may extend orthogonally to the local surface of the deformable absorber 30, and may have a height for example of the order of some tens of nanometres. As a variant or additionally, the deformable absorber 30 may also comprise at least one cut-out 35 (cf. FIG. 3H) located at the juncture between the fixed part 30.1 and the movable part, at the level of the face of the deformable absorber 30 opposite the substrate 10. A cut-out 35 is a local decrease in thickness of the absorbent layer 32 of shape-memory alloy, which remains non-zero.

Preferably, the deformable absorber 30 is made of a shape-memory alloy having a dynamic time constant Δt_{dyn} of deformation, in response to absorption of the high-power electromagnetic radiation, which is lower than a thermal time constant Δtₜₕ associated with excessive heating caused by this radiation. In other words, when the thermal detector 1 receives high-power electromagnetic radiation, the deformable absorber 30 deforms and passes from the flat detection configuration to the cooling curve configuration, which causes a maladjustment of the quarter-wave interference cavity and therefore degradation of the absorption of the electromagnetic radiation, and therefore a decrease of the temperature T of the deformable absorber 30, before the temperature T reaches the threshold temperature Tₜₕ of protection of the thermistor material 23. For this, the shape-memory alloy is advantageously selected from, for example, Ti_{85.3-x}NiₓHf_{14.7} with x>50% in at %, Ti₅₀₋ₓNi₅₀Cuₓ with x>7.5% in at %, Ti₈₂₋ₓNiₓZr₁₈ with x>₄₉% in at %, Ti_{50.5}Ni_{24.5}Pd₂₅, among others.

Thus, the deformable absorber 30 based on a shape-memory alloy makes it possible to improve the protection of the thermal detector 1, and more precisely of the thermometric transducer 23, when the latter is subjected to high-power electromagnetic radiation.

In fact, in the absence of said electromagnetic radiation, the temperature T of the deformable absorber 30 is equal to a nominal temperature, which is less than or equal to the austenite start temperature Aₛ. The deformable absorber 30 thus has a flat detection configuration, in which it extends in approximately planar fashion with respect to the reflector 3. The quarter-wave interference cavity is thus not degraded, which makes it possible to maximize the absorption of the electromagnetic radiation of interest by the deformable absorber 30.

When high-power electromagnetic radiation is present, for example solar radiation or a laser beam, the temperature T of the deformable absorber 30 increases and becomes greater than the austenite start temperature Aₛ. The deformable absorber 30 thus passes from the flat detection configuration to the cooling curve configuration, in which its extension is approximately curved with respect to the XY plane parallel to the reflector 3. The properties of the quarter-wave interference cavity are then degraded, which causes a decrease in absorption of the high-power electromagnetic radiation by the deformable absorber 30, and leads to a decrease of the temperature T.

Thus, the threshold effect associated with the inverse martensitic transformation of a shape-memory alloy is thus utilized for protecting the thermal detector 1 against excessive heating, while maintaining a non-degraded quarter-wave interference cavity in the absence of said high-power electromagnetic radiation.

FIGS. 3A to 3H illustrate different steps of a method for fabricating a thermal detector 1 according to another embodiment. In this example, the thermal detector 1 is produced using mineral sacrificial layers intended to be removed subsequently by wet etching in acid medium (HF vapour). As a variant, the sacrificial layers may be made on the basis of polyimide or equivalent and be removed subsequently by dry etching, for example under O₂ plasma. In this case, the materials of the protective layers 31, 33 are adapted to be inert to this type of dry etching, and may be selected from AlN, Al₂O₃, amorphous carbon, amorphous silicon, among others.

Referring to FIG. 3A, the reading substrate 10 is produced, formed from a supporting substrate 11 containing the reading circuit adapted for controlling and reading the thermal detector 1. The reading circuit thus comprises conducting portions 13 that are flush with the upper face boa of the reading substrate 10, which is approximately flat. The conducting portions 13 and the conducting vias 14 may be made of copper, aluminium and/or tungsten, among others, for example by a damascene process in which trenches made in the inter-metal insulating layer are filled. The conducting portions 13 may be made flush with the level of the upper face boa by a technique of chemical mechanical planarization (CMP).

The reflector 3 of the thermal detector 1 is also produced. Here, the reflector 3 is formed by a portion of a conductor of the last level of interconnection, the latter being made of a metallic material adapted to reflect the electromagnetic radiation to be detected. It is intended to extend opposite the membrane 20, and is intended to form, with the deformable absorber 30, a quarter-wave interference cavity with respect to the electromagnetic radiation to be detected.

A protective layer 15 may then be deposited, so as to cover the inter-metal insulating layer 12. This etching barrier layer 15 is made of a material that is substantially inert to the etchant used subsequently for removing the mineral sacrificial layers, for example the HF medium in vapour phase. It thus makes it possible to prevent etching of the underlying mineral insulating layers 12 during this step of removing the sacrificial layers. It may be formed from an aluminium oxide or nitride, aluminium trifluoride, or intrinsic amorphous silicon (not intentionally doped). It may be deposited for example by PVD (physical vapour deposition) and may have a thickness of the order of about ten nanometres to some hundreds of nanometres.

Referring to FIG. 3B, anchoring pillars 4 are produced. For this, a first sacrificial layer 41 is deposited on the reading substrate 10, for example made of a mineral material such as a silicon oxide SiOₓ deposited by plasma-enhanced chemical vapour deposition (PECVD). This mineral material is removable by wet chemical etching, in particular by chemical etching in an acid medium, the etchant preferably being hydrofluoric acid (HF) in the vapour phase. This sacrificial mineral layer 41 is deposited so as to extend continuously over substantially the whole surface of the reading substrate 10 and thus cover the etching barrier layer 15. The thickness of the sacrificial layer 41 along the Z axis makes it possible to define the height of the membrane 20. It may be of the order of some hundreds of nanometres to some microns.

Vertical apertures are then produced, intended for forming the anchoring pillars 4. They are produced by photolithography and etching, and go through the sacrificial mineral layer 41 and the protective layer 15, opening onto the conducting portions 13 of the reading circuit. The vertical apertures may have a cross-section in the (X,Y) plane of square, rectangular, or circular shape, with an area approximately equal for example to 0.25 μm². The anchoring pillars 4 are then produced in the vertical apertures. They may be made by filling the apertures with one or more electrically conducting materials. As an example, they may each comprise a layer of TiN deposited by PVD or MOCVD (metal organic chemical vapour deposition) on the vertical flanks of the apertures, and a copper or tungsten core filling the space delimited transversely by the layer of TiN. A CMP step then makes it possible to remove the excess filling materials and planarize the upper face formed by the sacrificial layer 41 and the anchoring pillars 4.

Referring to FIG. 3C, the heat-insulating arms 5 and the thermometric transducer membrane 20, here a thermistor membrane 20, are produced. The heat-insulating arms 5 provide thermal insulation of the membrane 20 with respect to the reading substrate 10, electrical connection of the thermistor material 23, and help to keep the membrane 20 suspended above the reading substrate 10. For this, here a lower dielectric layer 21 is deposited on the sacrificial layer 41, then a conductive layer 22 and an intermediate dielectric layer 25. Electrical contact between the anchoring pillars 4 and the conductive layer 22 is obtained by apertures made beforehand through the lower dielectric layer 21 and filled with the material of the conductive layer 22. The conductive layer 22 is thus in contact with the upper end of the anchoring pillars 4. It is made of an electrically conducting material, for example TiN with a thickness of some nanometres to some tens of nanometres, for example 10 nm. The lower 21 and intermediate 25 dielectric layers may be made of amorphous silicon, silicon carbide, alumina Al₂O₃ or aluminium nitride, among others. They may have a thickness of some tens of nanometres, for example 20 nm, and they help to stiffen the heat-insulating arms 5.

The thermistor membrane 20 is formed here from a stack of the lower insulating layer 21, two electrodes 22 derived from the conductive layer and insulated from one another by a lateral gap, the intermediate insulating layer 25 covering the polarization electrodes 22 and the lateral spacing, apart from in two apertures opening onto the electrodes 22, a thermistor material 23, for example amorphous silicon or a vanadium or titanium oxide. The thermistor material 23 is in contact with the two electrodes 22 via the apertures. An upper protective layer 26 is then deposited so as to cover the thermistor material 23 and optionally the intermediate dielectric layer 25 at the level of the heat-insulating arms 5. It makes it possible to protect the thermistor material 23 against the chemical etchant used during subsequent removal of the mineral sacrificial layers. A structuring of the dielectric layers 21, 25, of the conductive layer 22, and of the upper protective layer 26 is then carried out by photolithography and localized etching, so as to define the heat-insulating arms 5 in the XY plane, as well as the thermistor membrane 20. The structure of the membrane 20 is given here for purposes of illustration, and other structures may be used.

Referring to FIG. 3D, a second sacrificial layer 42 is then deposited, and then a second lower protective layer 31. The second sacrificial layer 42 thus covers the thermistor membrane 20 as well as the heat-insulating arms 5. A CMP step may be carried out in such a way that the upper face of the sacrificial layer 42 becomes flush with the level of that of the upper protective layer 26. The sacrificial layer 42 is preferably made of a material identical to that of the first sacrificial layer 41. The lower protective layer 31 is then deposited so as to cover the second sacrificial layer 42. It is preferably made of a material that makes it possible to protect the shape-memory alloy during a subsequent step of removing the sacrificial layers. It may be made of a silicon nitride or oxide, with a thickness for example of 10 nm.

Referring to FIG. 3E, an absorbent layer 32 of shape-memory alloy is then deposited. The absorbent layer 32 is deposited so as to cover the lower protective layer 31. It has a constant thickness at the level of the fixed and free parts, selected so as to adapt its impedance to that of a vacuum. The thickness may thus be between 5 nm and 25 nm, for example. The shape-memory alloy may be a metal alloy of NiTi in which the atomic proportion of nickel and titanium, as well as optional additional chemical elements, makes it possible to obtain an austenite start temperature Aₛ equal to the temperature T₂ and below a threshold temperature of protection Tₜₕ. The shape-memory alloy may thus be selected from Ti_{85.3-x}NiₓHf_{14.7} with x>50% in at %, Ti₈₂₋ₓNiₓZr₁₈ with x>49% in at %, Ti₇Ni₁₁Zr₄₃Cu₃₉₋ₓCoₓ with x>10% in at %, Ti₅₀Ni₅₀₋ₓPtₓ with x<25% in at %, Ti_{50.5}Ni_{24.5}Pd₂₅, Ti₅₁Ni₃₈Cu₁₁, Ti₅₀₋ₓNi₅₀Cuₓ with x>_{7.5}% in at %, or an alloy of the TiNiCuAlMn family. Next, advantageously, projecting features 34, i.e. protuberances, of shape-memory alloy are produced. These protuberances 34 are arranged at the level of a face of the absorbent layer 32 opposite the substrate 10 and are located in a zone intended to form the free part 30.2. They may extend, continuously or not, around the fixed part 30.1. Thus, the zones intended to form the fixed part 30.1 and free part 30.2 have an approximately constant thickness, except at the level of the protuberances 34. The thickness of the protuberances 34 may be of the order of 5 nm to 100 nm, and may preferably be between 10 nm and 50 nm.

Referring to FIG. 3F, a second upper protective layer 33 is then deposited, so as to cover the absorbent layer 32 of shape-memory alloy continuously. The upper protective layer 33 therefore extends over the zones intended to form the fixed part 30.1 and free part 30.2, and covers the protuberances 34. It is preferably made with a material and a thickness identical to those of the lower protective layer 31.

Referring to FIG. 3G, the stack of the lower protective layer 31 and upper protective layer 33, as well as the absorbent layer 32, is then structured by photolithography and etching, so as to form the deformable absorber 30 arranged opposite the reflector 3. The deformable absorber 30 thus comprises a fixed part 30.1 resting in contact with the membrane 20, and a part 30.2, here peripheral, intended to be free, i.e. able to deform as a function of its temperature. To improve the obtaining of deformation of the free part 30.2 in the +Z direction when the temperature of the deformable absorber 30 exceeds the temperature Aₛ, advantageously a cut-out 35 is made, by partial etching of the absorbent layer 32 and of the upper protective layer 33, located at the juncture between the fixed part 30.1 and the free part 30.2. As a variant, the cut-out 35 may be made prior to deposition of the upper protective layer 33.

Referring to FIG. 3H, the various sacrificial layers 41, 42 are removed so as to suspend the three-dimensional structure 2, and therefore the membrane 20 above the reading substrate 10, and the free part 30.2 of the deformable absorber 30 above the membrane 20. Suspension may be carried out after encapsulating the thermal detector 1 in a casing (not shown) defining a cavity under vacuum, intended to be hermetic. Suspension may be obtained by chemical etching of the various mineral sacrificial layers 41, 42, here by wet chemical etching by attack with hydrofluoric acid in the vapour phase.

Thus, a thermal detector 1 is obtained, comprising a three-dimensional structure 2 formed from a lower stage containing the thermistor membrane 20, and an upper stage containing the deformable absorber 30. The latter is formed on the basis of a shape-memory alloy, which makes it possible to ensure deformation of the deformable absorber 30 and absorb the electromagnetic radiation of interest. It comprises a fixed part 30.1, which rests in contact with the thermistor membrane 20, and a free part 30.2, which is spaced from the latter. Thus, below an austenite start temperature Aₛ, the deformable absorber 30 has a flat detection configuration, in which it is spaced from the reflector 3 by the constant distance d_{d} in the XY plane. The quarter-wave interference cavity is not perturbed then, which maximizes the absorption of the electromagnetic radiation of interest by the deformable absorber 30. Beyond this temperature Aₛ, the deformable absorber 30 has a cooling curve configuration in which the free part 30.2 is spaced from the reflector 3 by a distance dᵣ different from the value d_{d}. The quarter-wave interference cavity is then perturbed, which decreases the absorption of the high-power electromagnetic radiation by the deformable absorber 30 and causes cooling thereof and therefore of the thermistor membrane 20. The thermal detector 1 thus has improved protection against high-power electromagnetic radiation, while optimizing the absorption of the electromagnetic radiation of interest in the absence of excessive heating.

Furthermore, since the shape-memory alloy has a dynamic time constant Δt_{dyn} advantageously lower than the thermal time constant Δtₜₕ associated with heating of the deformable absorber 30 when it is subjected to high-power electromagnetic radiation, the shape-memory alloy deforms and quickly passes from the flat detection configuration to the cooling curve configuration, thus limiting any excessive heating of the deformable absorber 30 and therefore of the thermistor membrane 20, and therefore any risk of degradation of the thermistor material 23. Thus, there is cooling of the thermistor membrane 20 before the temperature of the latter reaches or exceeds the threshold temperature of protection Tₜₕ of the thermistor material 23.

Particular embodiments have just been described. Many variants and modifications will be apparent to a person skilled in the art.

Thus, FIG. 4A illustrates a variant embodiment that differs from the embodiment illustrated in FIG. 3H essentially in that the membrane 20 comprises an interposed portion 27 that rests on the thermistor material 23, here on the upper protective layer 26. The interposed portion 27 is made of a heat-conducting material. Here, it is located at the centre of the membrane 20 and here at the centre of the thermistor material 23. It has an upper face forming the supporting surface for the deformable absorber 30. The supporting surface has an extension lower than that of the upper protective layer 26 at the level of the thermistor material 23. The deformable absorber 30 then has a deformation length, in the XY plane, greater than if it rested in contact with the upper protective layer 26. Thus, the deformable absorber 30, in the cooling curve configuration, has a free part 30.2, adapted to deform, which extends peripherally around a fixed part 30.1 that rests on the interposed portion 27. The free part 30.2 has a larger area in the XY plane, which leads to perturbation of the quarter-wave interference cavity over a larger zone in the XY plane, and therefore leads to a larger decrease of the absorption of the electromagnetic radiation of interest, and therefore of the temperature of the deformable absorber 30.

FIG. 4B is a schematic illustration of another variant, which differs from that illustrated in FIG. 4A essentially in that the interposed portion 27 is located at the edge of the thermistor material 23. Thus, the deformable absorber 30 comprises a free part 30.2, adapted to deform, located opposite the thermistor material 23, which extends in the XY plane starting from the fixed part 30.1.

Moreover, FIG. 4B illustrates another example of structure of the membrane 20. In this example, the membrane 20 does not comprise an intermediate dielectric layer located between the thermistor material 23 and the polarization electrodes 22. It thus comprises a lower dielectric layer 21, made of a dielectric material, for example of a silicon oxide, a silicon nitride or a silicon oxynitride. It may also be made of a semiconductor material having an electrical resistivity lower than the dielectric materials, but having a lower thermal conductivity, such as amorphous silicon with high electrical resistivity. As an example, for a thermistor material 23 with electrical resistivity of 10 Ω·cm and with a thickness of 80 nm, the lower dielectric layer 21 may be made of amorphous silicon with a thickness of 40 nm and with an electrical resistivity greater than or equal to 1000 Ω·cm. Generally, the lower dielectric layer 21 has a thickness for example between 10 nm and 100 nm, preferably between 30 nm and 50 nm. It helps to provide stiffening of the heat-insulating arms 5.

Two polarization electrodes 22 extend in a planar manner over the lower dielectric layer 21 and in contact with the latter. They are spaced apart by a lateral spacing for example of the order of 5 μm to 10 μm for a pixel pitch of the order of 12 μm, so as to avoid electrical shunting of the thermistor material 23. The thermistor material 23 rests in contact with the polarization electrodes 22, and rests in contact with the lower dielectric layer 21. An upper dielectric layer 24 covers the thermistor material 23 and the polarization electrodes 22. It preferably has a material identical or similar to that of the lower dielectric layer 21, and preferably has an identical thickness. It contributes advantageously to stiffening of the heat-insulating arms 5. This example of membrane 20 is given for purposes of illustration, and other structures may be used.

1-11. (canceled)

12. A thermal detector adapted for detecting electromagnetic radiation, comprising:
a substrate;
a reflector of said electromagnetic radiation;
a three-dimensional structure configured to detect said electromagnetic radiation, suspended above the substrate and thermally insulated from the substrate, comprising:
a membrane comprising a thermometric transducer,
an absorber of said electromagnetic radiation,
resting on the membrane and partly spaced from the latter, and connected thermally to the thermometric transducer,
spaced with respect to the reflector so as to form a quarter-wave interference cavity for electromagnetic radiation,
wherein the absorber is:
formed on the basis of a shape-memory alloy having an inverse martensitic transformation of a martensitic phase into an austenitic phase of said alloy starting from an austenite start temperature Aₛ, and
configured to have:
a detection configuration when its temperature is less than or equal to a first threshold temperature T₁, in which it extends in a flat manner in a plane parallel to the reflector, and
a cooling configuration when its temperature is above a predetermined second threshold temperature T₂ equal to the austenite start temperature Aₛ, in which it extends at least partly in a curved manner with respect to a plane parallel to the reflector.

13. The thermal detector according to claim 12, wherein the shape-memory alloy has a volume fraction χₘ of the martensitic phase, and has the flat detection configuration when the volume fraction χₘ is greater than or equal to 0.95, and has the cooling curve configuration when the volume fraction χₘ is less than 0.95.

14. The thermal detector according to claim 12, wherein the shape-memory alloy has a volume fraction χₘ of the martensitic phase, and has a volume fraction χₘ less than or equal to 0.05 when its temperature is greater than or equal to an austenite finish temperature A_{f}, said austenite finish temperature A_{f} being below a predetermined threshold temperature Tₜₕ for protection of the thermometric transducer.

15. The thermal detector according to claim 12, wherein the deformable absorber comprises a fixed part resting in contact with the membrane, and a free part configured to deform as a function of the temperature of the deformable absorber and extending from the fixed part and spaced from the membrane.

16. The thermal detector according to claim 12, wherein the shape-memory alloy is a metal alloy based on NiTi.

17. The thermal detector according to claim 12, wherein the shape-memory alloy is a metal alloy selected from Ti_{85.3-x}NiₓHf_{14.7} with x>50 at %, Ti₈₂₋ₓNiₓZr₁₈ with x>49 at %, Ti₇Ni₁₁Zr₄₃Cu₃₉₋ₓCoₓ with x>10 at %, Ti₅₀Ni₅₀₋ₓPtₓ with x<25 at %, Ti_{50.5}Ni_{24.5}Pd₂₅, Ti₅₁Ni₃₈Cu₁₁, Ti₅₀₋ₓNi₅₀Cuₓ with x>7.5 at %, or an alloy based on TiNiCuAlMn.

18. The thermal detector according to claim 12, wherein the deformable absorber comprises an absorbent layer of shape-memory alloy having protuberances arranged on a face of the absorbent layer opposite the substrate.

19. The thermal detector according to claim 12, wherein the deformable absorber comprises an absorbent layer of shape-memory alloy having at least one cut-out formed from a face of the absorbent layer opposite the substrate.

20. The thermal detector according to claim 12, wherein the substrate has a flat upper face, and wherein the three-dimensional structure is maintained above the upper face of the substrate by heat-insulating arms, and by anchoring pillars that extend approximately orthogonally to the plane of the upper face of the substrate.

21. The thermal detector according to claim 20, wherein the substrate comprises a reading circuit, the three-dimensional structure being connected electrically to the reading circuit by the anchoring pillars and by the heat-insulating arms.

22. A method for fabricating the thermal detector according to claim 12, comprising the following steps:
supplying a substrate;
depositing at least one first sacrificial layer on the substrate;
making anchoring pillars through the first sacrificial layer;
making heat-insulating arms and a membrane containing a thermometric transducer on the first sacrificial layer;
depositing at least one second sacrificial layer so as to cover the heat-insulating arms and the membrane;
making the absorber on the second sacrificial layer, so that it rests at least partly on the membrane;
removing the first and second sacrificial layers.
